(19) United States
(12) Patent Application Publication
(10) Pub. No.: US 2024/0040765 A1
(43) Pub. Date: Feb. 1, 2024

(54) METHOD OF MANUFACTURING SEMICONDUCTOR STRUCTURE AND SEMICONDUCTOR STRUCTURE

(71) Applicant: CHANGXIN MEMORY TECHNOLOGIES, INC., Hefei City (CN)

(72) Inventor: Yue ZHUO, Hefei City (CN)

(21) Appl. No.: 17/935,610

(22) Filed: Sep. 27, 2022

(30) Foreign Application Priority Data
Jul. 29, 2022 (CN) 202210466432.6

(51) Int. Cl. H01L 27/108

(52) U.S. Cl. CPC H01L 27/10855; H01L 27/10814

(57) ABSTRACT

The present disclosure provides a method of manufacturing a semiconductor structure and a semiconductor structure, and relates to the technical field of semiconductors. The method of manufacturing a semiconductor structure includes: providing a base; and sequentially forming a plurality of stacked first structures on the base, where a method for forming the first structures includes: forming a sacrificial layer; forming a plurality of first conductive segments disposed at intervals in the sacrificial layer, where tops of the first conductive segments are exposed outside the sacrificial layer; and forming a support layer on a top surface of the sacrificial layer, where the support layer is at least partially formed on surfaces of some of the first conductive segments exposed outside the sacrificial layer, the support layer is provided with openings, and the openings expose parts of the sacrificial layer.

### CROSS-REFERENCE TO RELATED APPLICATION

This application claims the priority of Chinese Patent Application No. 202210466432.6, submitted to the Chinese Intellectual Property Office on Apr. 29, 2022, the disclosure of which is incorporated herein in its entirety by reference.

### TECHNICAL FIELD

The present disclosure relates to the technical field of semiconductors, and in particular, to a method of manufacturing a semiconductor structure and a semiconductor structure.

### BACKGROUND

The dynamic random access memory (DRAM) has advantages of a small size, a high degree of integration, and low power consumption, and is faster than the read-only memory (ROM). With the continuous development of the semiconductor industry, the demands for semiconductor structures become increasingly high.

As the size of the capacitor structure continues to shrink, the line width of the capacitor hole in the capacitor structure becomes increasingly small. To ensure the capacitance value of the capacitor structure, the height of the capacitor structure is not significantly reduced, which leads to an increasingly large aspect ratio of the capacitor hole. As a result, it is more difficult to perform the subsequent etching process and increase the capacitance value of the capacitor structure.

### SUMMARY

An overview of the subject described in detail in the present disclosure is provided below. This overview is not intended to limit the protection scope of the claims.

The present disclosure provides a method of manufacturing a semiconductor structure and a semiconductor structure.

A first aspect of the present disclosure provides a method of manufacturing a semiconductor structure. The method of manufacturing a semiconductor structure includes:
providing a base; and
sequentially forming a plurality of stacked first structures in a direction perpendicular to the base, where a method for forming the first structures includes:
forming a sacrificial layer;
forming a plurality of first conductive segments disposed at intervals in the sacrificial layer, where tops of the first conductive segments are exposed outside the sacrificial layer; and
forming a support layer on a top surface of the sacrificial layer, where the support layer is at least partially formed on surfaces of some of the first conductive segments exposed outside the sacrificial layer, the support layer is provided with openings, and the openings expose parts of the sacrificial layer; and
the sacrificial layers in adjacent two of the first structures are connected by using the openings.

A second aspect of the present disclosure provides a semiconductor structure, including:
a base;
first conductive structures, arranged on the base, where each of the first conductive structures includes a plurality of stacked first conductive segments; and
a support segment, where the support segment includes a plurality of support layers disposed at intervals, and the support layers are each at least disposed on a partial outer surface of the first conductive segment; and
in a direction perpendicular to the base, the support layers have a same height or not, and are in different shapes.

Other aspects of the present disclosure are understandable upon reading and understanding of the accompanying drawings and detailed description.

### BRIEF DESCRIPTION OF THE DRAWINGS

The accompanying drawings incorporated into the specification and constituting a part of the specification illustrate the embodiments of the present disclosure, and are used together with the description to explain the principles of the embodiments of the present disclosure. In these accompanying drawings, similar reference numerals represent similar elements. The accompanying drawings in the following description illustrate some rather than all of the embodiments of the present disclosure. Those skilled in the art may obtain other accompanying drawings based on these accompanying drawings without creative efforts.

FIG. 1 is a flowchart of a method of manufacturing a semiconductor structure according to an exemplary embodiment;

FIG. 2 is a flowchart for forming a first structure in the method of manufacturing a semiconductor structure according to an exemplary embodiment;

FIG. 3 is a schematic diagram of forming the first structure and openings in the method of manufacturing a semiconductor structure according to an exemplary embodiment;

FIG. 4 is a schematic diagram of forming a second first structure and openings in the method of manufacturing a semiconductor structure according to an exemplary embodiment;

FIG. 5 is a schematic diagram of forming a third first structure and openings in the method of manufacturing a semiconductor structure according to an exemplary embodiment;

FIG. 6 is a schematic diagram of removing a sacrificial layer in the method of manufacturing a semiconductor structure according to an exemplary embodiment;

FIG. 7 is a schematic diagram of forming a dielectric layer in the method of manufacturing a semiconductor structure according to an exemplary embodiment.

FIG. 8 is a schematic diagram of forming a second conductive structure and a capacitor structure in the method of manufacturing a semiconductor structure according to an exemplary embodiment;

FIG. 9 is a schematic diagram of forming a first sacrificial layer and a first initial support layer in the method of manufacturing a semiconductor structure according to an exemplary embodiment;

FIG. 10 is a schematic diagram of forming a first capacitor hole in the method of manufacturing a semiconductor structure according to an exemplary embodiment;

FIG. 11 is a schematic diagram of forming a first conductive segment in the method of manufacturing a semiconductor structure according to an exemplary embodiment;

FIG. 12 is a schematic diagram of forming a second mask pattern and a first pattern hole in the method of manufacturing a semiconductor structure according to an exemplary embodiment;

FIG. 13 is a schematic diagram of forming first openings in the method of manufacturing a semiconductor structure according to an exemplary embodiment;

FIG. 14 is a schematic diagram of forming a second sacrificial layer and a second initial support layer in the method of manufacturing a semiconductor structure according to an exemplary embodiment;

FIG. 15 is a schematic diagram of forming a second capacitor hole in the method of manufacturing a semiconductor structure according to an exemplary embodiment;

FIG. 16 is a schematic diagram of forming a second conductive segment in the method of manufacturing a semiconductor structure according to an exemplary embodiment;

FIG. 17 is a schematic diagram of forming a fourth mask pattern and a second pattern hole in the method of manufacturing a semiconductor structure according to an exemplary embodiment;

FIG. 18 is a schematic diagram of forming second openings in the method of manufacturing a semiconductor structure according to an exemplary embodiment;

FIG. 19 is a cross-sectional top view of forming a support layer in the method of manufacturing a semiconductor structure according to an exemplary embodiment; and

FIG. 20 is a cross-sectional top view of forming another support layer in the method of manufacturing a semiconductor structure according to an exemplary embodiment.

### DETAILED DESCRIPTION

To make the objectives, technical solutions, and advantages of the embodiments of the present disclosure clearer, the following clearly and completely describes the technical solutions in the embodiments of the present disclosure with reference to the accompanying drawings in the embodiments of the present disclosure. Apparently, the described embodiments are some rather than all of the embodiments of the present disclosure. All other embodiments obtained by those skilled in the art based on the embodiments of the present disclosure without creative efforts should fall within the protection scope of the present disclosure. It should be noted that the embodiments in the present disclosure and features in the embodiments may be combined with each other in a non-conflicting manner.

The DRAM has advantages of a small size, a high degree of integration, and low power consumption, and is faster than the ROM. With the continuous development of the semiconductor industry, the demands for the use of semiconductor structures get increasingly high.

As the size of the capacitor structure continues to shrink, the line width of the capacitor hole in the capacitor structure becomes increasingly small. To ensure the capacitance value of the capacitor structure, as the density of the capacitor structure increases, the height of the traditional capacitor structure does not decrease but continues to increase, which leads to an increasingly large aspect ratio of the capacitor hole. As a result, it is more difficult to perform the subsequent etching process and increase the capacitance value of the capacitor structure. On the other hand, the support layer on the outer sidewall of the lower electrode in the capacitor structure needs to be opened through etching, and then the oxide layer (that is, the sacrificial layer) between the adjacent support layers is removed through wet etching. However, as the aspect ratio of the capacitor hole used to make the capacitor structure increases, it becomes increasingly difficult to open the support layer located in the middle of the capacitor structure. Thus, the processing becomes increasingly difficult, and it is also difficult to add more support layers in the traditional method of manufacturing the capacitor structure.

To resolve one of the foregoing problems, the present disclosure provides a method of manufacturing a semiconductor structure, and a semiconductor structure. When the semiconductor structure is manufactured, openings are formed in the support layer of the first structures, the sacrificial layers in two adjacent first structures are connected by using the openings, and the first structures form capacitor structures, to resolve the problem that it is difficult to open a plurality of support layers in the capacitor structures, and reduce the aspect ratio of a single etching, such that the line width of the capacitor structure is easier to control, thereby improving the performance and yield of the semiconductor structure.

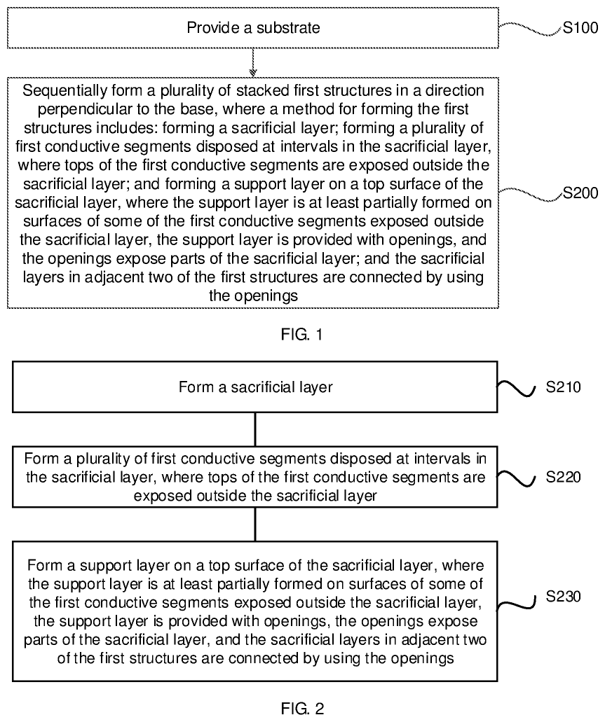

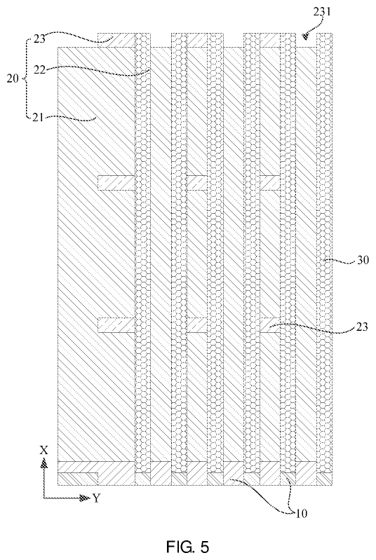

According to an exemplary embodiment, this embodiment provides a method of manufacturing a semiconductor structure, which is described with reference to FIGS. 1 to 20.

The semiconductor structure is not limited in this embodiment. Description is made by using an example in which the semiconductor structure is the DRAM, but this embodiment is not limited thereto. Alternatively, the semiconductor structure in this embodiment may be another structure.

As shown in FIG. 1, the method of manufacturing a semiconductor structure in this embodiment includes:
Step S100: Provide a base.
Step S200: Sequentially form a plurality of stacked first structures in a direction perpendicular to the base, where a method for forming the first structures includes:
forming a sacrificial layer;
forming a plurality of first conductive segments disposed at intervals in the sacrificial layer, where tops of the first conductive segments are exposed outside the sacrificial layer; and
forming a support layer on a top surface of the sacrificial layer, where the support layer is at least partially formed on surfaces of some of the first conductive segments exposed outside the sacrificial layer, the support layer is provided with openings, and the openings expose parts of the sacrificial layer; and
the sacrificial layers in adjacent two of the first structures are connected by using the openings.

In this embodiment, description is made by using an example in which the plurality of stacked first structures form a capacitor structure. As shown in FIG. 2, the method of manufacturing the first structure includes:
Step S210: Form a sacrificial layer.
Step S220: Form a plurality of first conductive segments disposed at intervals in the sacrificial layer, where tops of the first conductive segments are exposed outside the sacrificial layer.
Step S230: Form a support layer on a top surface of the sacrificial layer, where the support layer is at least partially formed on surfaces of some of the first conductive segments exposed outside the sacrificial layer, the support layer is provided with openings, the openings expose parts of the sacrificial layer, and the sacrificial layers in adjacent two of the first structures are connected by using the openings.

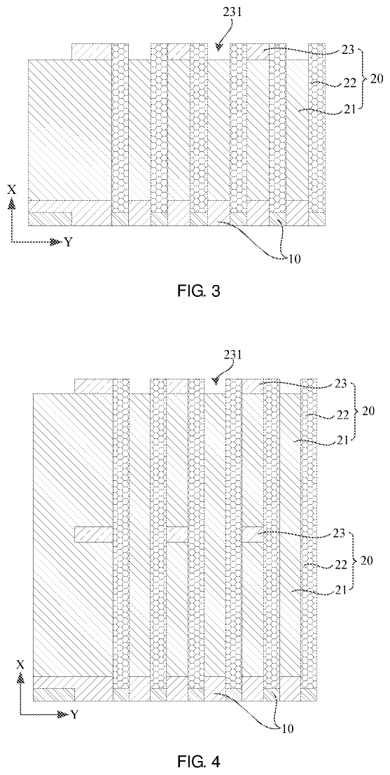

As shown in FIG. 3, in step S100, the base 10 is used as a support component of the DRAM to support other components provided thereon. For example, the base 10 may be provided with structures such as a word line structure, a bit line structure, and an active region. The base 10 may be made of a semiconductor material. The semiconductor material may be one or more selected from the group consisting of silicon, germanium, a silicon-germanium compound, and a silicon-carbon compound.

In step S200, the description in this embodiment is made by using the orientation shown in FIG. 5 as an example, and the extension direction from the bottom surface of the base 10 to the top surface of the base 10 is defined as the first direction X. In a direction perpendicular to the base 10, that is, along the extension direction of the first direction X, a plurality of stacked first structures 20 are formed sequentially on the top surface of the base 10.

A plurality of stacked first structures 20 and the base 10 form a semiconductor structure. A plurality of stacked first structures 20 may be subjected to various processes to form a plurality of discrete capacitor structures or other semiconductor structures (for example, contact plugs). It should be noted that, taking the orientation shown in FIG. 3 as an example, the extension direction parallel to the front side surface of the base 10 is defined as the second direction Y A plurality of discrete capacitor structures or other semiconductor structures are arranged at intervals along the second direction Y, and the first direction X and the second direction Y intersect or are perpendicular to each other.

In step S210, as shown in FIG. 3, a sacrificial layer 21 is formed on the base 10 through a physical vapor deposition process or a chemical vapor deposition process. The material of the sacrificial layer 21 may include, but is not limited to, tetraeth oxysilane (TEOS), silicon oxide, silicon nitride, silicon carbide, or polysilicon. Alternatively, the material of the sacrificial layer 21 may further be a soft material such as phosphoro silicate glass (PSG), a boro-phospho-silicate glass (BPSG), or a fluoro silicate glass (FSG).

In step S220, with reference to FIG. 3, an etching process may be used to form a plurality of grooves (not shown in the figure) spaced along the second direction Y in the sacrificial layer 21. Then, a first initial conductive layer (not shown in the figure) is deposited in the groove through the physical vapor deposition process or the chemical vapor deposition process. The first initial conductive layer extends to fill up the entire groove, and extends outside the groove to cover the top surface of the sacrificial layer 21. After the first initial conductive layer is formed, a mask layer (not shown in the figure) and a photoresist layer (not shown in the figure) are formed on the first initial conductive layer through the physical vapor deposition process or a chemical vapor deposition process. A mask pattern (not shown in the figure) is formed on the photoresist layer through exposure or development and etching. The photoresist layer with the mask pattern is used as a mask, to etch and remove the first initial conductive layer beside the groove. The first initial conductive layer is retained in the groove, and the top of the part of the first conductive layer is exposed outside the sacrificial layer 21. The retained initial conductive layer forms the first conductive segment 22, and the top of the first conductive segment 22 is exposed outside the sacrificial layer 21.

The first conductive segment 22 can be used to form a part of the lower electrode in the capacitor structure. The first conductive segments 22 in the stacked first structures 20 are electrically connected together to form the lower electrodes of the capacitor structures. The material of the first conductive segment 22 may include, but is not limited to, polysilicon, tungsten, titanium nitride and other conductive materials.

In step S230, with reference to FIGS. 3, 4, and 5, after the first conductive segment 22 is formed, an initial support layer (not shown in the figure) is formed on the top surface of the sacrificial layer 21 through the physical vapor deposition process or the chemical vapor deposition process. Then, an etching process is used to remove a part of the initial support layer beside a part of the first conductive segment 22. Thus, a plurality of openings 231 each exposing a part of the top surface of the sacrificial layer 21 are formed in the initial support layer. The retained initial support layer forms the support layer 23. The support layer 23 is formed at least partially on a partial surface of the first conductive segment 22 exposed outside the sacrificial layer 21.

It should be noted that, along the first direction X, the sacrificial layers 21 in two adjacent first structures 20 are connected through the openings 231. A plane parallel to the top surface of the base 10 is used as a cross section. The cross-sectional shape of the opening 231 in this embodiment may be a rectangle, a square or some other feasible shapes. The cross-sectional shape of the opening 231 is not limited in this embodiment.

In this embodiment, during the formation of the capacitor structure, after a first conductive segment and an initial support layer are formed each time, parts of the initial support layer between first conductive segments in two adjacent first structures are removed, such that openings are formed in the initial support layer, and expose parts of the sacrificial layer. After a plurality of stacked first structures are formed, the plurality of first conductive segments are sequentially electrically connected to all the sacrificial layers in the plurality of first structures to form a whole. In this method, a support layer between adjacent sacrificial layers is opened first, and then the sacrificial layers formed a plurality of times are connected, such that the sacrificial layers are removed in an etching step in the subsequent process, thereby reducing the aspect ratio of a single etching, and resolving the problem that it is difficult to open a plurality of support layers of capacitor structures in the related art, such that the line width of the capacitor structure is easier to control, and the performance and yield of the semiconductor structure is increased.

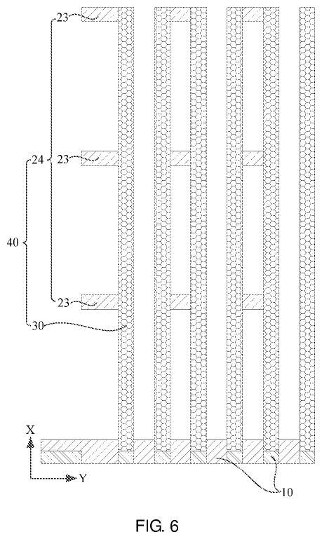

According to one exemplary embodiment, as shown in FIG. 6, this embodiment includes the method in the above embodiment. Details are not described herein again. The difference between the foregoing embodiment and this embodiment is that, after a plurality of stacked first structures 20 are formed, the method of manufacturing the semiconductor structure in this embodiment further includes: The sacrificial layers 21 in the plurality of first structures 20 are removed in the same step to prepare for the subsequent formation of capacitor structures, that is, the sacrificial layers 21 in the first structures 20 are removed in one etching process, and when a first structure 20 is formed every time, it is unnecessary to remove the sacrificial layer 21 in the first structure, thereby reducing the quantity of times of etching to be performed in the whole process, and the preparation and subsequent processing steps between processes, and improving the processing efficiency.

That is, when the support layer 23 of each first structure 20 is formed, openings 231 are formed in the support layer 23. Along the first direction X, the sacrificial layers 21 in the adjacent two first structures 20 can be connected through the openings 231. Therefore, regardless of a quantity of layers of the first structures 20, all sacrificial layers 21 in the first structures 20 formed a plurality of times are connected as a whole, such that in a same etching step, all sacrificial layers 21 can be etched by using the openings 231 between the support layers 23, thereby reducing the process difficulty, reducing the aspect ratio of a single etching, and resolving the problem that it is difficult to open a plurality of layers of support layers of capacitor structures in the related art.

After the sacrificial layers 21 in the semiconductor structure are all removed, in a direction perpendicular to the base 10, first conductive segments 22 in the first structures 20 form a first conductive structure 30, and the first conductive structure 30 may include a lower electrode in the capacitor structure. The support layers 23 in the first structures 20 form a support segment 24, and the support segment 24 and the first conductive structure 30 form an intermediate structure 40.

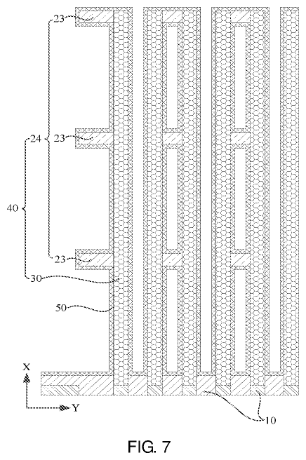

As shown in FIG. 7, in some embodiments, after the intermediate structure 40 is formed, the method of manufacturing the semiconductor structure further includes:

The dielectric layer 50 covering the intermediate structure 40 is formed through the physical vapor deposition process or the chemical vapor deposition process.

The material of the dielectric layer 50 may include at least one selected from the group consisting of dielectric materials such as a high-K material, tantalum oxide, hafnium oxide, zirconium oxide, niobium oxide, titanium oxide, barium oxide, strontium oxide, yttrium oxide, lanthanum oxide, praseodymium oxide, and barium strontium titanate.

In an example, the dielectric layer 50 may be a laminated structure. For example, the dielectric layer 50 may be of a three-layer structure, and the materials of the three layers are zirconia, alumina, and zirconia, respectively, that is, the dielectric layer 250 may include a zirconium oxide layer, an aluminum oxide layer, and a zirconium oxide layer connected sequentially.

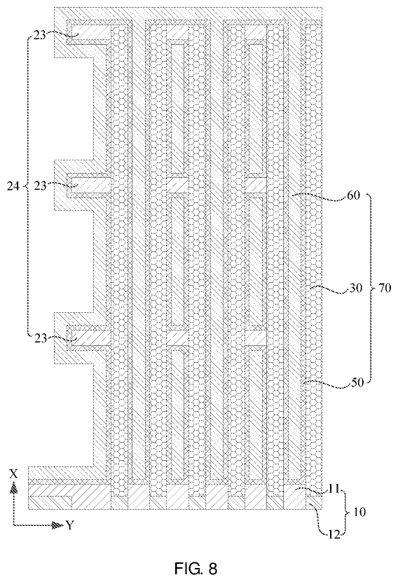

With reference to FIG. 8, after the dielectric layer 50 is formed, the physical vapor deposition process or the chemical vapor deposition process is used to form a second conductive structure 60 covering the dielectric layer 50. The second conductive structure 60 may include an upper electrode in the capacitor structure. The intermediate structure 40, the dielectric layer 50, and the second conductive structure 60 form a capacitor structure 70.

In this embodiment, the first conductive structure may be formed by stacking three or more layers of the first conductive segments, the dielectric layer covering the intermediate structure (that is, the first conductive structure and the support segment) is formed, and a second conductive structure covering the dielectric layer is formed, thereby forming a higher capacitor structure with a larger capacitance value in the semiconductor structure, and effectively improving the performance of the semiconductor structure.

According to an exemplary embodiment, this embodiment is a further description of step S100 described above.

In some embodiments, the base 10 may be formed by using the following method.
Step S110: Provide a substrate.
Step S120: Form a plurality of contact structures disposed at intervals in the substrate, where the first conductive segments in the first structures in connection with the substrate are respectively connected to the contact structures in one-to-one correspondence.

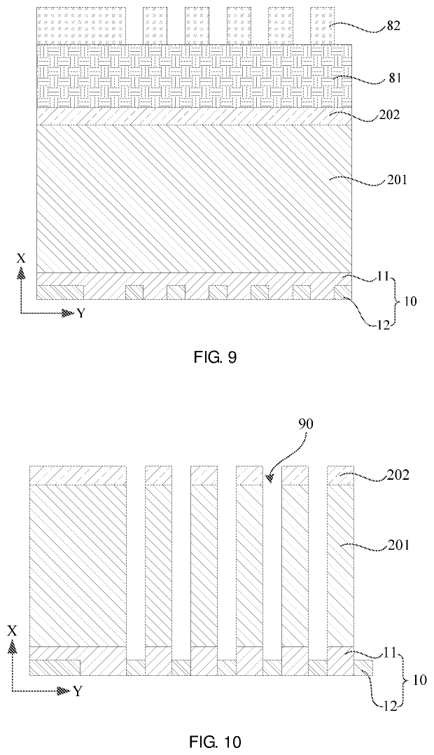

With reference to FIG. 9, the material of the substrate 11 in step S110 is the same as the material of the base 10 in the above description. Details are not repeated here.

In step 210, an etching process is used to form a plurality of grooves (not shown in the figure) spaced along the second direction Y on the substrate 11. The contact structure 12 (with reference to FIG. 9) is deposited and formed in the groove through the atomic layer deposition process, a physical vapor deposition process, or a chemical vapor deposition process.

In an example, when the gate structure formed on the active region in the substrate 11 is a buried gate structure, it can be used as a recessed channel transistor structure subsequently. The active region further includes a source-drain region. The contact structure 12 may be set as one of the source-drain regions, and is used as a capacitor contact structure to be connected to the capacitor structure 70.

In another example, when the structure formed on the active region in the substrate 11 is a planar gate structure, a planar transistor structure can be fabricated subsequently, and the formed transistor may be located in the peripheral region of the DRAM chip. The active region further includes a source-drain region, and the contact structure 12, as an electrode extraction structure, may be at least one of a source-drain region and a gate structure of the active region disposed in the substrate 11. The electrode extraction structure can be used to apply a working voltage to the semiconductor structure to extract a working current.

In this embodiment, the contact structure may be used to connect the structure (for example, a source/drain) in the active region to the capacitor structure formed subsequently, to ensure that the semiconductor structure has better electrical properties.

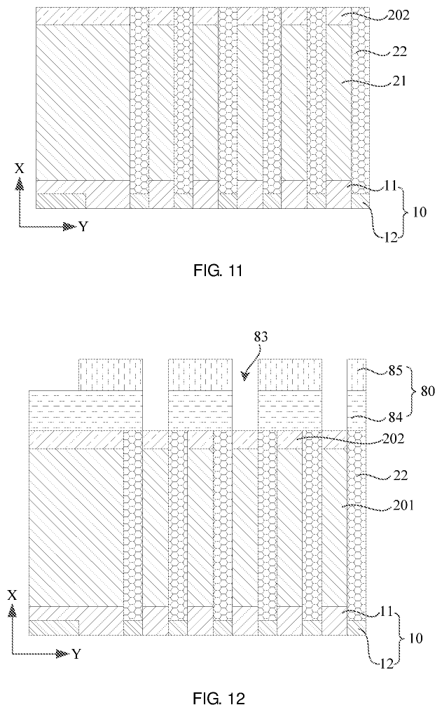

The first conductive segments 22 in the first structures 20 in connection with the substrate 11 are respectively connected to the contact structures 12 in one-to-one correspondence (with reference to FIG. 11). The material of the contact structure 12 may include but is not limited to polysilicon, titanium nitride or tungsten, to effectively ensure the electrical conductivity between components such as the capacitor structure and the active region in the base, and the usage performance of the semiconductor structure.

According to an exemplary embodiment, this embodiment is a further description of step S200.

In some embodiments, the plurality of stacked first structures 20 may be further formed sequentially by using the following method: A stacked two-layer first structure 20 is used as an example.

First, as shown in FIG. 9, a first sacrificial layer 201 and a first initial support layer 202 on the first sacrificial layer 201 are formed on the base 10 through the atomic layer deposition process, the physical vapor deposition process, or the chemical vapor deposition process.

Then, with reference to FIG. 10, first mask pattern (not shown in the figure) are provided, and the first initial support layer 202 and the first sacrificial layer 201 are etched based on the first mask pattern, to form first capacitor holes 90 penetrating the first initial support layer 202 and the first sacrificial layer 201 along the first direction X. The first capacitor holes 90 are arranged at intervals along the second direction Y A bottom of the first capacitor hole 90 extends into the substrate 11, and exposes a top surface of the contact structure 12.

In an example, with reference to FIG. 9, the first capacitor hole 90 may be formed by using the following method.

A first hard mask layer 81 and first pattern layers 82 on the first hard mask layer 81 are formed on the first initial support layer 202 through the physical vapor deposition process or the chemical vapor deposition process. In this step, after the first hard mask layer 81 is formed, the first pattern layers 82 are deposited on the first hard mask layer 81. The first pattern layer 82 may be a patterned photoresist layer. The first hard mask layer 81 is etched by using the photoresist layers with a mask pattern as a mask to form the first capacitor holes 90 (with reference to FIG. 10). The height of the first capacitor hole 90 formed each time can be controlled to be lower, such that the line width of the first capacitor hole 90 is easier to be adjusted in the etching process when the aspect ratio is small.

With reference to FIG. 11, after the first capacitor hole 90 is formed, the physical vapor deposition process or the chemical vapor deposition process is used to deposit a conductive material in the first capacitor hole 90 to form the first conductive segment 22.

With reference to FIGS. 12 and 13, after the first conductive segment 22 is formed, second mask pattern 80 are provided, and the first initial support layer 202 is etched based on the second mask pattern 80, to remove parts of the first initial support layer 202, and form a plurality of first openings 2311 in the first initial support layer 202. The remaining parts of the first initial support layer 202 form the first support layer 241.

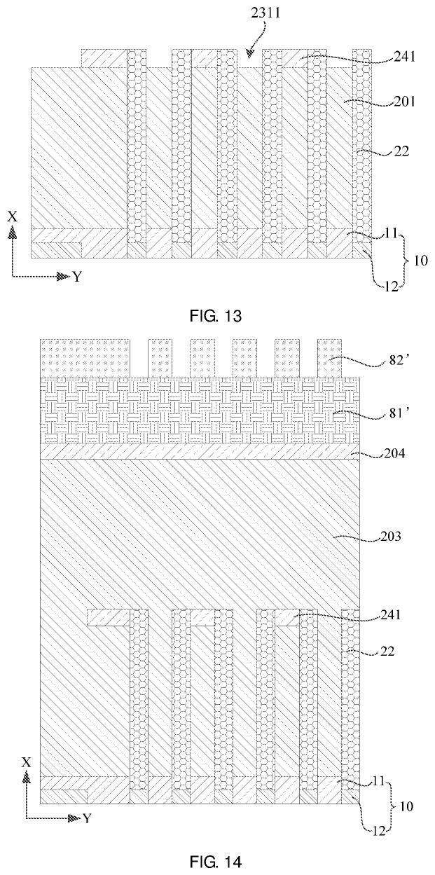

With reference to FIG. 14, a second sacrificial layer 203 is deposited on the first support layer 241 and the first conductive segment 22 through the physical vapor deposition process or the chemical vapor deposition process, and the second sacrificial layer 203 and the first sacrificial layer 201 are connected through the first openings 2311. The material of the second sacrificial layer 203 is the same as that of the first sacrificial layer 201.

A second initial support layer 204 is deposited on the second sacrificial layer 203 through the physical vapor deposition process or the chemical vapor deposition process.

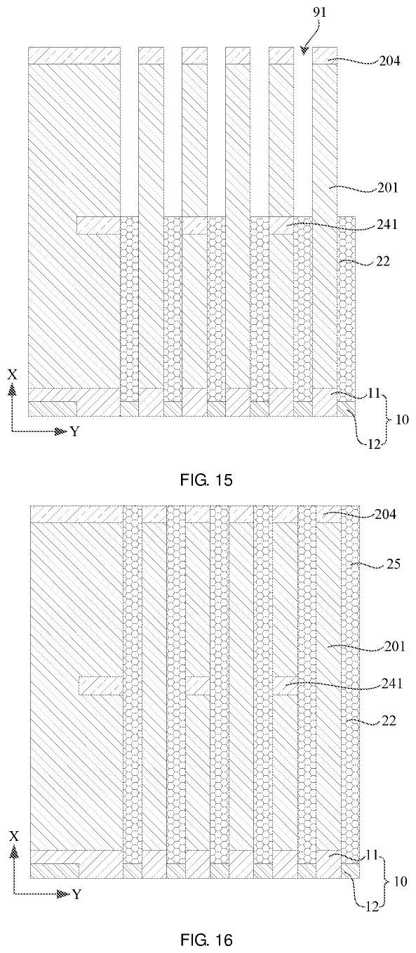

With reference to FIG. 14, third mask pattern (not shown in the figure) are provided. The formation process of the third mask pattern includes: forming a second hard mask layer 81′ on the second initial support layer 204, and third pattern layers 82′ on the second hard mask layer 81′. In this step, after the second hard mask layer 81′ is formed, the third pattern layers 82′ are deposited on it. The third pattern layer 82′ may be a patterned photoresist layer. The second hard mask layer 81′ is etched by using the photoresist layers with a mask pattern as a mask to form the second capacitor holes 91 (with reference to FIG. 15). With reference to FIG. 15, the second capacitor holes 91 expose at least parts of the first conductive segments 22. It should be noted that the first capacitor hole 90 communicates with the second capacitor hole 91. However, orthographic projection of the first capacitor hole 90 on the substrate 11 partially or completely overlaps that of the second capacitor hole 91 on the substrate 11.

With reference to FIG. 16, after the second capacitor hole 91 is formed, the physical vapor deposition process or the chemical vapor deposition process is used to deposit a conductive material in the second capacitor hole 91 to form the second conductive segment 25. The second conductive segment 25 is connected to the first conductive segment 22.

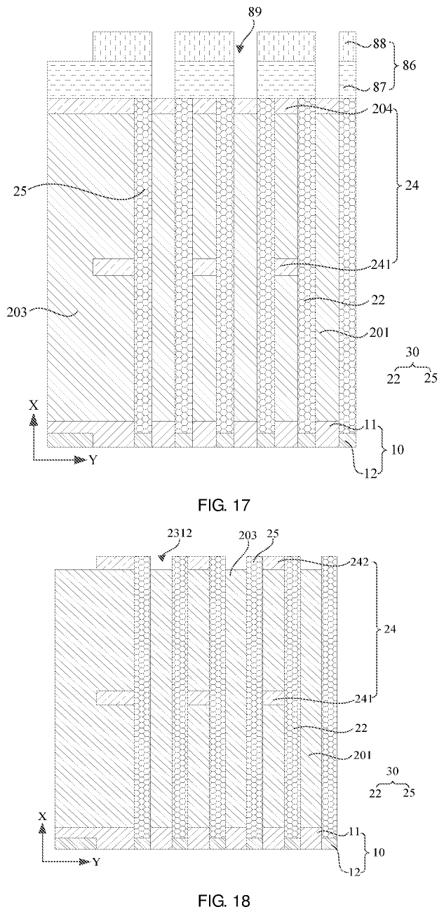

With reference to FIG. 17, after the second conductive segment 25 is formed, fourth mask pattern 86 are provided, and the second initial support layer 204 is etched based on the fourth mask pattern 86, to remove parts of the second initial support layer 204, and form a plurality of second openings 2312 in the second initial support layer 204. The remaining parts of the second initial support layer 204 form a second support layer 242. The second support layer 242 and the first support layer 241 are made of a same material.

The first support layer 241 and the second support layer 242 form the support segment 24. The first conductive segment 22 and the second conductive segment 25 form the first conductive structure 30.

It should be noted that, taking a plane parallel to the top surface of the substrate 11 as a cross-section, the cross-sectional shapes of the first conductive segment 22 and the second conductive segment 25 may be the same or different. The cross-sectional shape of the first conductive segment 22 may include, but is not limited to, a circle or an ellipse, and the cross-sectional of the second conductive segment 25 may include, but is not limited to, a circle or an ellipse. The cross-sectional area of the first conductive segment 22 is equal to or unequal to the cross-sectional area of the second conductive segment 25. An example is made in which the cross-sectional shapes of the first conductive segment 22 and the second conductive segment 25 are both circular or elliptical. The cross-sectional area of the second conductive segment 25 may be larger than the cross-sectional area of the first conductive segment 22, such that the second conductive segment 25 can be quickly electrically connected to the first conductive segment 22, thereby improving the self-alignment efficiency between the two. Taking a plane perpendicular to the top surface of the substrate 11 as a longitudinal cross section, the longitudinal cross-sectional shapes of the first conductive segment 22 and the second conductive segment 25 may include, but are not limited to, a square, a truncated cone, and the like. Their longitudinal cross-sectional shapes may be the same or different. The longitudinal cross-sectional shapes of the first conductive segment 22 and the second conductive segment 25 are both squares or truncated cones. Alternatively, the longitudinal cross-sectional shape of the first conductive segment 22 is a square, and the longitudinal cross-sectional shape of the second conductive segment 25 is a truncated cone, and vice versa.

In this embodiment, the first conductive structure (for example, the lower electrode of the capacitor structure) is composed of segments. After the first conductive segment is formed, the corresponding first support layer is opened by using the first openings, and after the second conductive segment is formed, the second openings are used to open the corresponding second support layer, thereby removing the first sacrificial layer and the second sacrificial layer in the same step in the subsequent process, and reducing the difficulty of subsequent manufacturing processes. In this case, because the etching height of the single-layer support layer is relatively low, the thickness of the mask layer configured to etch the first capacitor hole and the second capacitor hole can also be reduced, thereby reducing the processing costs.

As shown in FIGS. 12 and 13, in some embodiments, the first openings 2311 may be formed by using the following method.

Second mask pattern 80 are formed on the first initial support layer 202 through the physical vapor deposition process or the chemical vapor deposition process.

The second mask pattern 80 may be formed by using the following method:

A first mask layer 84 and a second pattern layer 85 on the first mask layer 84 are formed on the first initial support layer 202 through the physical vapor deposition process or the chemical vapor deposition process. The material of the first mask layer 84 may include, but is not limited to, silicon nitride, silicon oxide, silicon oxynitride, polysilicon, amorphous carbon, and the like. The second pattern layer 85 may be a photoresist layer.

Then, with reference to FIG. 12, after the first mask layer 84 and the second pattern layer 85 are formed, the pattern of the second pattern layer 85 is transferred to the first mask layer 84 through etching, and the second mask pattern 80 with a plurality of first pattern holes 83 is formed. Each of the first pattern holes 83 exposes at least a part of the first initial support layer 202 between two adjacent first conductive segments 22.

With reference to FIG. 13, the first initial support layer 202 is etched along the first pattern holes 83, thereby forming the plurality of first openings 2311 exposing parts of the first sacrificial layer 201 in the first initial support layer 202.

The first mask layer 84 and the second pattern layers 85 are removed through an etching process, and the remaining parts of the first initial support layer 202 each are formed between at least two adjacent first conductive segments 22.

In some embodiments, the second openings 2312 may be formed by using the following method:

With reference to FIG. 17, fourth mask pattern 86 are formed on the second initial support layer 204 through the physical vapor deposition process or the chemical vapor deposition process.

In an example, the fourth mask pattern 86 may be formed by using the following method:

With reference to FIG. 17, a second mask layer 87 and a fourth pattern layer 88 on the second mask layer 87 are formed on the second initial support layer 204 through the physical vapor deposition process or the chemical vapor deposition process. The fourth patterned layer 88 may be a patterned photoresist layer.

Then, after the second mask layer 87 and the fourth pattern layer 88 are formed, the pattern of the fourth pattern layer 88 is transferred to the second mask layer 87 through etching, and the fourth mask pattern 86 with a plurality of second pattern holes 89 is formed. Each of the second pattern holes 89 exposes at least a part of the second initial support layer 204 between two adjacent second conductive segments 25.

With reference to FIG. 18, the second initial support layer 204 is etched along the second pattern holes 89, thereby forming the plurality of second openings 2312 exposing parts of the second sacrificial layer 203 in the second initial support layer 204.

The second mask layer 87 and the fourth pattern layers 88 are removed through an etching process, and the remaining parts of the second initial support layer 204 each are formed between at least two adjacent second conductive segments 25.

It should be noted that, after the second openings 2312 are formed, other first structures 20 may be formed on the second support layer 242 according to the method for forming the first openings 2311 or the method for forming the second openings 2312, thereby increasing the length of the first conductive structure 30 in the first direction X. Then, with reference to FIGS. 5 to 8, and the formation process of the dielectric layer 50 and the second conductive structure 60, a capacitor structure with a larger storage capacity is formed to improve the performance of the semiconductor structure.

As shown in FIG. 18, in some embodiments, in a direction perpendicular to the substrate 11, the first sacrificial layer 201 and the second sacrificial layer 203 have a same height or not. The height of the first sacrificial layer 201 is the vertical distance between the bottom surface of the first support layer 241 and the top surface of the substrate 11. The height of the second sacrificial layer 203 is the vertical distance between the bottom surface of the second support layer 242 and the top surface of the first support layer 241.

In an example, the height of the first sacrificial layer 201 is the same as that of the second sacrificial layer 203, to reduce the difficulty of manufacturing the semiconductor structure.

In another embodiment, the first sacrificial layer 201 and the second sacrificial layer 203 have different heights. According to the specific structure of the first conductive structure 30, different support layers are designed at different heights on the side of the first conductive structure 30, to ensure the subsequent formation quality of the first conductive structure 30.

In some embodiments, to facilitate the fabrication of semiconductor structures in different sizes, and improve the flexibility of the design of the first conductive structure 30, in the direction perpendicular to the substrate 11, the heights of the first initial support layer 202 and the second initial support layer 204 are the same or different.

The first initial support layer 202 and the first support layer 241 have a same height, and the second initial support layer 204 and the second support layer 242 have a same height. With reference to FIG. 18, the heights of the first support layer 241 and the second support layer 242 are the same. In this case, when the height of the first sacrificial layer 201 and the height of the second sacrificial layer 203 are also the same, a same spacing distance is ensured, and support layers with a same thickness are deposited. The same deposition process parameters can be used to deposit a plurality of support layers, which effectively reduces the process difficulty of the semiconductor structure, and can also effectively ensure the stability of the first conductive segment formed each time, thereby controlling the elongated first conductive structure that is easy to twist, preventing the short circuit of adjacent capacitor structures, and improving the formation accuracy of the capacitor structure and the performance of the semiconductor structure.

In some embodiments, the first mask pattern and the third mask pattern may be the same or different. The first mask pattern is subsequently used to form the first capacitor hole 90, and the third mask pattern is subsequently used to form the second capacitor hole 91.

In an example, the first mask pattern is the same as the third mask pattern, and the structures of the first capacitor hole 90 and the second capacitor hole 91 are the same. In other words, the cross-sectional shape, cross-sectional area, and longitudinal cross-sectional shape of the first capacitor hole 90 are the same as those of the second capacitor hole 91, to reduce the difficulty of the subsequent manufacturing process of the first conductive structure 30.

In another example, when the first mask pattern is different from the third mask pattern, refer to the description of the foregoing embodiment for sequentially forming the plurality of stacked first structures 20. Details are not repeated herein.

In some embodiments, the second mask pattern and the fourth mask pattern may be the same or different. The second mask pattern is subsequently configured to form the first openings 2311. Correspondingly, after the first openings 2311 are formed, the remaining first initial support layer 202 forms the first support layer 241. The fourth mask pattern is subsequently configured to form the second openings 2312. Correspondingly, after the second openings 2312 are formed, the remaining second initial support layer 204 forms the second support layer 242.

In an example, the second mask pattern and the fourth mask pattern are the same, and the structures of the first opening 2311 and the second opening 2312 are the same. The cross-sectional shape, cross-sectional area and longitudinal cross-sectional shape of the first opening 2311 are the same as those of the second opening 2312, such that the structures of the first support layer 241 and the second support layer 242 are the same, thereby reducing the process difficulty and process costs of the semiconductor structure.

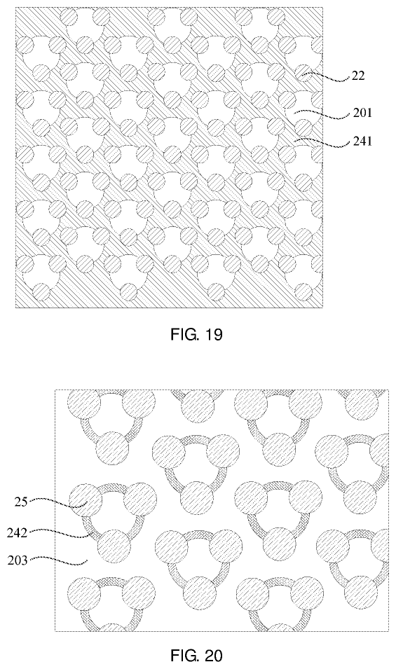

In another example, as shown in FIGS. 19 and 20, the second mask pattern and the fourth mask pattern are different, that is, the structures of the first support layer 241 and the second support layer 242 formed finally are different. For example, the cross-sectional shape of the first support layer 241 is shown in FIG. 19, and the cross-sectional shape of the second support layer 242 is shown in FIG. 20. Alternatively, the cross-sectional shape of the first support layer 241 is in FIG. 20, and the cross-sectional shape of the second support layer 242 is in FIG. 19.

When there are two or more first structures 20, the structure of one of the support layers may be different from that of any one of the other support layers. Taking a part of the support layer 23 between adjacent first conductive structures 30 as an example, the cross-sectional shape of the part of the support layer 23 may include, but is not limited to, a square, an arc, a ring, and the like.

As shown in FIG. 8, an exemplary embodiment of the present disclosure provides a semiconductor structure. The semiconductor structure includes: a base 10, first conductive structures 30, and a support segment 24.

The base 10 includes a substrate 11 and a plurality of contact structures 12 disposed at intervals in the substrate 11. The contact structures 12 are arranged at intervals along a second direction Y, and the contact structures 12 are connected to the first conductive structures 30 in one-to-one correspondence. The contact structure 12 is electrically connected to the first conductive structure 30.

A first conductive structure 30 is disposed on the base 10. The first conductive structure 30 includes a plurality of stacked first conductive segments 22. The first end of each first conductive structure 30 extends into the substrate 11 and is connected to the contact structure 12, and the second end of each first conductive structure 30 is flush with the topmost layer in the support layers 23.

The support segment 24 includes a plurality of support layers 23 arranged at intervals along the first direction X, and each support layer 23 is disposed at least on a part of an outer surface of the first conductive segment 22. In the direction perpendicular to the base 10, the heights of the support layers 23 are the same or different. The formations of the support layers 23 are different, and the plane parallel to the top surface of the base 10 is used as the cross section. The cross-sectional shapes of the support layers 23 may include, but are not limited to, a square, an arc, a ring, and the like.

In one example, the arrangements, thicknesses, shapes, and sizes of the support layers 23 in each support segment 24 are the same, to reduce the difficulty of the manufacturing process.

In another example, the arrangements, thicknesses, shapes, sizes, and the like of the support layers 23 in two adjacent support segments 24 are different. Alternatively, the arrangements, thicknesses, shapes and sizes of the support layers 23 in one support segment 24 and in any one of the other support segments 24 may also be different. For example, in this example, when the cross-sectional shape of the support layer 23 is an arc, because the first conductive structure 30 in this embodiment is a segmented structure, during the formation of the first structure 20 in any one layer, there may be no support layer 23 around a part of the first conductive segment 22 in the layer. Then, in the process of forming first structures 20 of the next layer, the support layer 23 is formed around that part of the first conductive segment 22 without the support layer 23. In this way, this can ensure that there is at least a part of the support layer around each first conductive structure, thereby effectively reducing the area of the support layer and increasing the space area occupied by the capacitor structure. Thus, any support segment in any cross-sectional shape can be compatible with a capacitor structure of a high aspect ratio, and the problem is resolved that the support layers are difficult to open when the capacitor structure is in the form of a high capacitance, and the performance and yield of the semiconductor structure are improved.

In some embodiments, as shown in FIG. 8, the semiconductor structure includes a capacitor structure 70. The capacitor structure 70 includes an intermediate structure 40, and the intermediate structure 40 includes a first conductive structure 30 and a support segment 24.

The capacitor structure 70 further includes a dielectric layer 50 and a second conductive structure 60. With reference to FIG. 8, the dielectric layer 50 covers the outer surface of the intermediate structure 40, and the second conductive structure 60 covers the outer surface of the dielectric layer 50. It should be noted that the first conductive structure 30 may include a lower electrode in the capacitor structure, and the second conductive structure may include an upper electrode in the capacitor structure.

In this embodiment, the first conductive structure is composed of a plurality of stacked first conductive segments. Because each time the first conductive segment is formed, openings are formed in the support layers beside the first conductive segments. The openings effectively solve the problem that the plurality of support layers are difficult to open when the existing concentrated capacitor structure is formed. After the first conductive structure is formed, the dielectric layer and the second conductive structure are sequentially formed, to effectively reduce the difficulty of the manufacturing process of the capacitor structure.

It should be noted that the material of the dielectric layer 50 may include a high-K material. The high-K material may be, for example, one of zirconium oxide (ZrOx), hafnium oxide (HfOx), titanium zirconium oxide (ZrTiOx), ruthenium oxide (RuOx), aluminum oxide (AIOx), or a combination thereof. In other words, the material of the dielectric layer may be one of the above materials, or may also be a combination or a mixture of the above materials. The material of the dielectric layer is the high-K material, facilitating increasing a capacitance value of the subsequent capacitor structure per unit area, increasing the storage capacity of the subsequently formed capacitor structure, and improving the performance of the semiconductor structure.

With reference to FIG. 8, in some embodiments, along the first direction X, spacings between two adjacent support layers 23 are the same or different. In other words, according to the specific structure of the capacitor structure, the support layers 23 may be formed in positions at a same height or different heights on both sides of the first conductive structure, to improve the applicability of the semiconductor structure.

It should be noted that, an example is made in which the support layers 23 have a same thickness. When there are three or more layers of the first structures 20, any two first structures 20 have the same height. Alternatively, two adjacent first structures 20 have the same height, but another first structure 20 is not as high as the foregoing two first structures 20. Alternatively, any two first structures 20 in the first structures 20 have the same height, and another first structure 20 is not as high as the two first structures 20.

The embodiments or implementations of this specification are described in a progressive manner, and each embodiment focuses on differences from other embodiments. The same or similar parts between the embodiments may refer to each other.

In the description of this specification, the description with reference to terms such as “an embodiment”, “an exemplary embodiment”, “some implementations”, “a schematic implementation”, and “an example” means that the specific feature, structure, material, or characteristic described in combination with the implementation(s) or example(s) is included in at least one implementation or example of the present disclosure.

In this specification, the schematic expression of the above terms does not necessarily refer to the same implementation or example. Moreover, the described specific feature, structure, material or characteristic may be combined in an appropriate manner in any one or more implementations or examples.

It should be noted that in the description of the present disclosure, the terms such as “center”, “top”, “bottom”, “left”, “right”, “vertical”, “horizontal”, “inner” and “outer” indicate the orientation or position relationships based on the accompanying drawings. These terms are merely intended to facilitate description of the present disclosure and simplify the description, rather than to indicate or imply that the mentioned apparatus or element must have a specific orientation and must be constructed and operated in a specific orientation. Therefore, these terms should not be construed as a limitation to the present disclosure.

It can be understood that the terms such as “first” and “second” used in the present disclosure can be used to describe various structures, but these structures are not limited by these terms. Instead, these terms are merely intended to distinguish one structure from another.

The same elements in one or more accompanying drawings are denoted by similar reference numerals. For the sake of clarity, various parts in the accompanying drawings are not drawn to scale. In addition, some well-known parts may not be shown. For the sake of brevity, a structure obtained by implementing a plurality of steps may be shown in one figure. In order to understand the present disclosure more clearly, many specific details of the present disclosure, such as the structure, material, size, processing process, and technology of the device, are described below. However, as those skilled in the art can understand, the present disclosure may not be implemented according to these specific details.

Finally, it should be noted that the above embodiments are merely intended to explain the technical solutions of the present disclosure, rather than to limit the present disclosure. Although the present disclosure is described in detail with reference to the above embodiments, those skilled in the art should understand that they may still modify the technical solutions described in the above embodiments, or make equivalent substitutions of some or all of the technical features recorded therein, without deviating the essence of the corresponding technical solutions from the scope of the technical solutions of the embodiments of the present disclosure.

1. A method of manufacturing a semiconductor structure, comprising:
providing a base; and
sequentially forming a plurality of stacked first structures in a direction perpendicular to the base, wherein a method for forming the first structures comprises:
forming a sacrificial layer;
forming a plurality of first conductive segments disposed at intervals in the sacrificial layer, wherein tops of the first conductive segments are exposed outside the sacrificial layer; and
forming a support layer on a top surface of the sacrificial layer, wherein the support layer is at least partially formed on surfaces of some of the first conductive segments exposed outside the sacrificial layer, the support layer is provided with openings, and the openings expose parts of the sacrificial layer; and
the sacrificial layers in adjacent two of the first structures are connected by using the openings.

2. The method of manufacturing a semiconductor structure according to claim 1, further comprising:
removing the sacrificial layers in the first structures in a same step, wherein
in the direction perpendicular to the base, the first conductive segments in the first structures form a first conductive structure, the support layers in the first structures form a support segment, and the support segment and the first conductive structure form an intermediate structure.

3. The method of manufacturing a semiconductor structure according to claim 2, further comprising:
forming a dielectric layer covering the intermediate structure; and
forming a second conductive structure covering the dielectric layer, wherein the intermediate structure, the dielectric layer, and the second conductive structure form a capacitor structure.

4. The method of manufacturing a semiconductor structure according to claim 1, wherein the providing a base comprises:
providing a substrate; and
forming a plurality of contact structures disposed at intervals in the substrate, wherein the first conductive segments in the first structures in connection with the substrate are respectively connected to the contact structures in one-to-one correspondence.

5. The method of manufacturing a semiconductor structure according to claim 4, wherein the sequentially forming a plurality of stacked first structures comprises:
forming a first sacrificial layer on the base and a first initial support layer on the first sacrificial layer;
providing a first mask pattern, and based on the first mask pattern, forming first capacitor holes penetrating the first initial support layer and the first sacrificial layer;
depositing a conductive material in the first capacitor holes, and forming the first conductive segments;
providing a second mask pattern, and based on the second mask pattern, removing parts of the first initial support layer, and forming a plurality of first openings, wherein remaining parts of the first initial support layer form a first support layer;
depositing a second sacrificial layer on the first support layer and the first conductive segments, wherein the second sacrificial layer and the first sacrificial layer are connected by using the first openings;
depositing a second initial support layer on the second sacrificial layer;
providing a third mask pattern, and based on the third mask pattern, forming second capacitor holes penetrating through the second sacrificial layer and the second initial support layer, wherein the second capacitor holes at least partially expose the first conductive segments;
depositing a conductive material in the second capacitor holes, and forming second conductive segments, wherein the second conductive segment is connected to the first conductive segment; and
providing a fourth mask pattern, and based on the fourth mask pattern, removing parts of the second initial support layer, and forming a plurality of second openings, wherein remaining parts of the second initial support layer form a second support layer; and
the first support layer and the second support layer form a support segment, and the first conductive segment and the second conductive segment form a first conductive structure.

6. The method of manufacturing a semiconductor structure according to claim 5, wherein the providing a second mask pattern, and based on the second mask pattern, removing parts of the first initial support layer, and forming a plurality of first openings comprises:
forming a first mask layer on the first initial support layer;
patterning the first mask layer, and forming the second mask pattern, wherein a plurality of first pattern holes are provided in the second mask pattern, and the first pattern holes each expose at least a part of the first initial support layer between adjacent two of the first conductive segments;
etching the first initial support layer along the first pattern holes, and forming the first openings exposing parts of the first sacrificial layer; and
removing the first mask layer, wherein remaining parts of the first initial support layer each are formed between at least adjacent two of the first conductive segments.

7. The method of manufacturing a semiconductor structure according to claim 6, wherein the providing a fourth mask pattern, and based on the fourth mask pattern, removing parts of the second initial support layer, and forming a plurality of second openings comprises:
forming a second mask layer on the second initial support layer;
patterning the second mask layer, and forming the fourth mask pattern, wherein a plurality of second pattern holes are provided in the fourth mask pattern, and the second pattern holes each expose a part of the second initial support layer and a part of the second conductive segment;
etching the second initial support layer along the second pattern holes, and forming the second openings exposing parts of the second sacrificial layer and parts of the second conductive segments; and
removing the second mask layer, wherein remaining parts of the second initial support layer each are formed on a partial outer surface of at least one of the second conductive segments.

8. The method of manufacturing a semiconductor structure according to claim 5, wherein in a direction perpendicular to the substrate, the first sacrificial layer and the second sacrificial layer have a same height or not.

9. The method of manufacturing a semiconductor structure according to claim 5, wherein in a direction perpendicular to the substrate, the first initial support layer and the second initial support layer have a same height or not.

10. The method of manufacturing a semiconductor structure according to claim 5, wherein the first mask pattern and the third mask pattern are the same or different.

11. The method of manufacturing a semiconductor structure according to claim 5, wherein the second mask pattern and the fourth mask pattern are the same or different.

12. A semiconductor structure, comprising:
a base;
first conductive structures, disposed on the base, wherein each of the first conductive structures comprises a plurality of stacked first conductive segments; and
a support segment, wherein the support segment comprises a plurality of support layers disposed at intervals, and the support layers are each at least disposed on a partial outer surface of the first conductive segment; and
in a direction perpendicular to the base, the support layers have a same height or not, and are in different shapes.

13. The semiconductor structure according to claim 12, wherein the semiconductor structure comprises a capacitor structure, the capacitor structure comprises an intermediate structure, and the intermediate structure comprises the first conductive structure and the support segment; and
the capacitor structure further comprises:
a dielectric layer, covering an outer surface of the intermediate structure; and
a second conductive structure, covering an outer surface of the dielectric layer.

14. The semiconductor structure according to claim 12, wherein spacings between the two adjacent support layers are the same or different.

15. The semiconductor structure according to claim 12, wherein the base comprises a substrate, a plurality of contact structures are disposed at intervals in the substrate, and the first conductive structures are connected to the contact structures in one-to-one correspondence.
